(19) United States
(12) Patent Application Publication
(10) Pub. No.: US 2015/0021457 A1
(43) Pub. Date: Jan. 22, 2015

(54) ANGLE ADJUSTING APPARATUS

(71) Applicant: HON HAI PRECISION INDUSTRY CO., LTD., New Taipei (TW)

(72) Inventor: PO-CHUN LIU, New Taipei (TW)

(73) Assignee: HON HAI PRECISION INDUSTRY CO., LTD., New Taipei (TW)

(21) Appl. No.: 14/183,519

(22) Filed: Feb. 18, 2014

(30) Foreign Application Priority Data
Jul. 18, 2013 (TW) 102125782

(51) Int. Cl. H05K 5/02; F16M 11/10

(52) U.S. Cl. CPC H05K 5/0234; F16M 11/10
USPC 248/688

(57) ABSTRACT

An angle adjusting apparatus for adjusting a supporting angle of an electronic device includes an inputting member defining a sliding slot, a sliding member slidably received in the sliding slot, a hinge rotatably connected to the sliding member, and a supporting arm rotatably connected to the hinge. When the supporting arm moves the sliding member relative to the inputting member via the hinge, the sliding member partially slides out of the sliding slot. The supporting arm is rotated around the hinge to support the electronic device. The electronic device is supported at different angles by the supporting arm according to different positions of the sliding member.

### BACKGROUND

1. Technical Field

The present disclosure relates to an angle adjusting apparatus for an electronic device.

2. Description of Related Art

Electronic devices, such as tablet computers, are placed on a supporting bracket to support the electronic device at an angle relative to a surface. However, the supporting brackets only support the tablet computers at a fixed angle.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an angle adjusting apparatus supporting an electronic device.

FIG. 2 is an exploded view of the angle adjusting apparatus of FIG. 1.

FIG. 3 is an assembled view of the angle adjusting apparatus in an original state.

FIG. 4 is similar to FIG. 3, but shows the angle adjusting apparatus supporting the electronic device at a first angle.

FIG. 5 is similar to FIG. 3, but shows the angle adjusting apparatus supporting the electronic device at a second angle.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

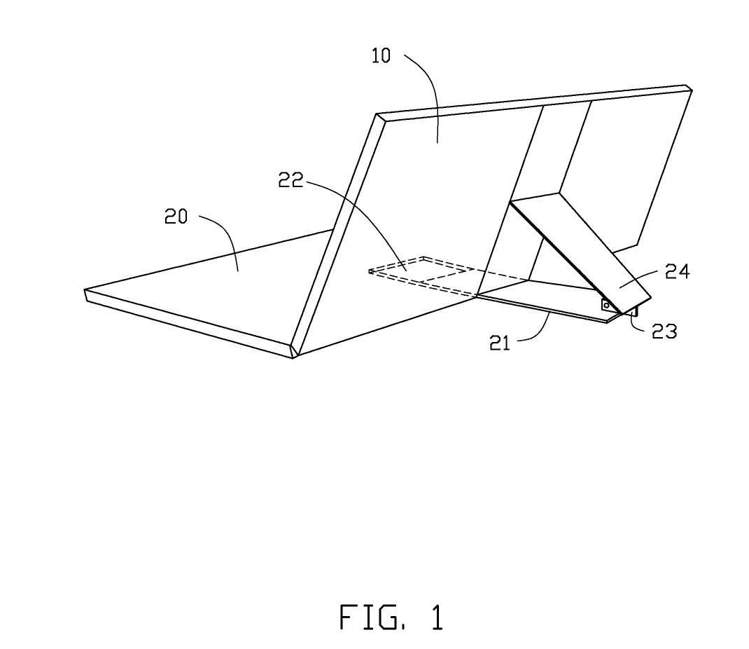

FIGS. 1 through 3 show an embodiment of an angle adjusting apparatus.

The angle adjusting apparatus is used to adjust an angle of an electronic device 10. The electronic device 10 can be, but is not limited to, a tablet computer, a personal digital assistant (PDA), a game machine, a digital video player, a wireless device, or a portable television.

The angle adjusting apparatus includes an inputting member 20 and a sliding member 21. A sliding slot 22 is defined in the inputting member 20. A first portion of the sliding member 21 is received in the sliding slot 22. A second portion of the sliding member 21 is rotatably connected to a first portion of a hinge 23. A second portion of the hinge 23 is rotatably connected to a first portion of a supporting arm 24. A second portion of the supporting arm 24 pressingly engages a side surface of the electronic device 10. The hinge 23 and the supporting arm 24 are rotatable relative to the inputting member 20 and the sliding member 21. In one embodiment, the inputting member 20 is a BLUETOOTH keyboard.

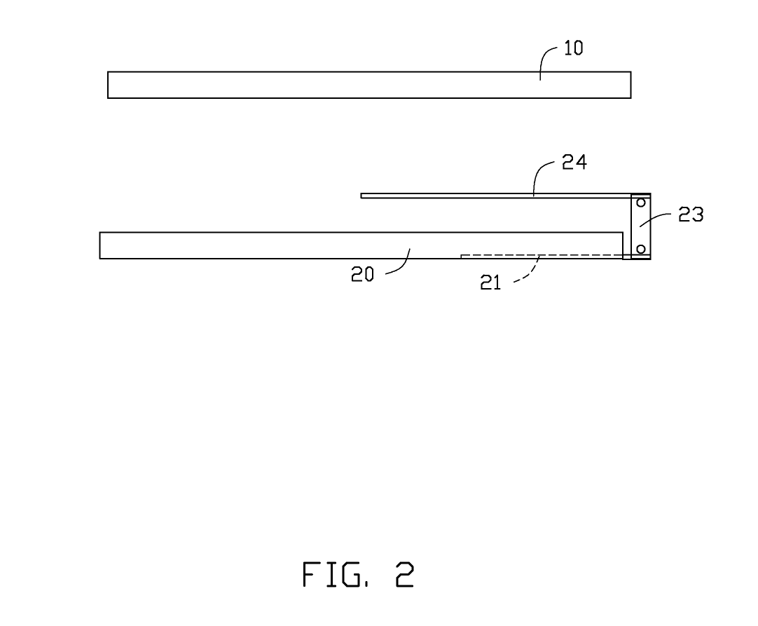

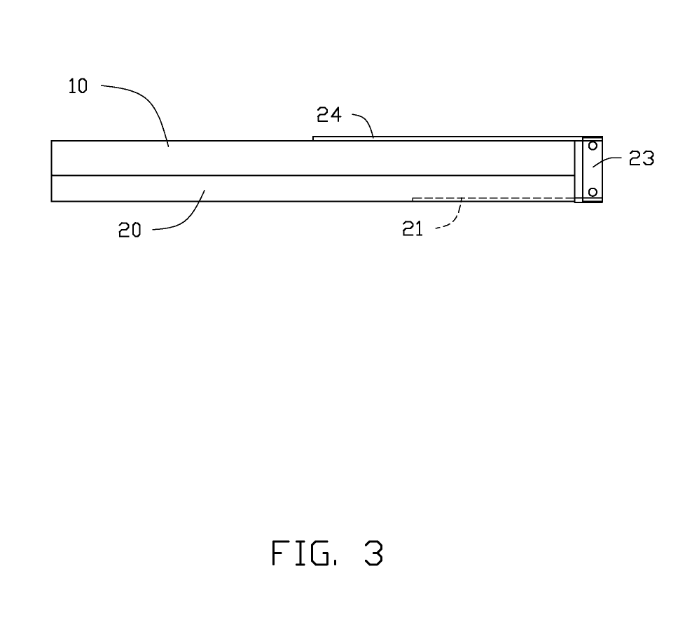

Referring to FIGS. 2 and 3, in assembly, the first portion of the sliding member 21 is slidably received in the sliding slot 22 of the inputting member 20. The electronic device 10 is placed on a top surface of the inputting member 20. In an original state, the electronic device 10 and the supporting arm 24 are substantially parallel to the inputting member 20 and the sliding member 21, and the hinge 23 is substantially perpendicular to the sliding member 21 and the supporting arm 24.

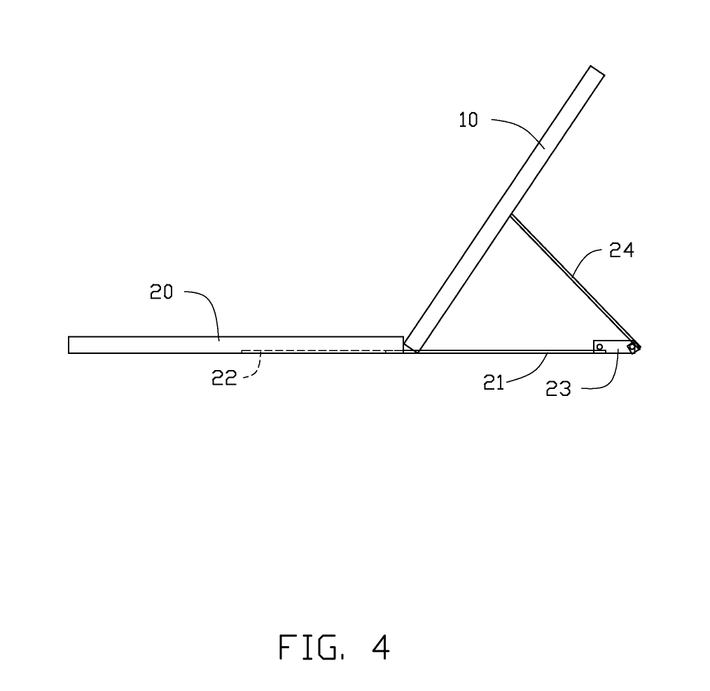

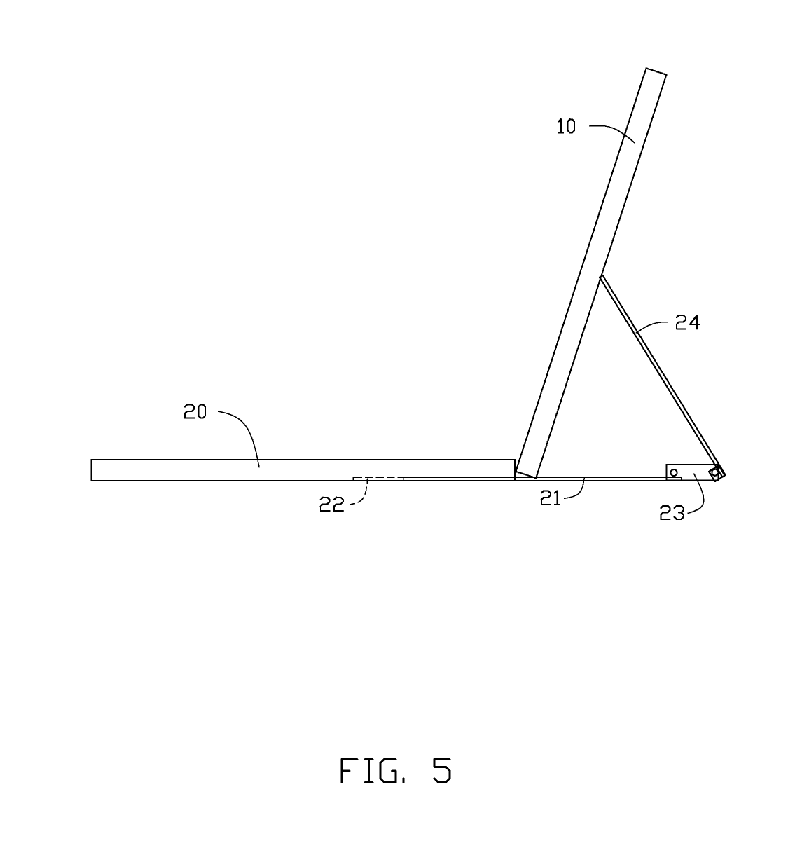

FIGS. 1 through 5 show that in use, the electronic device 10 is slid toward the hinge 23 to push the hinge 23. As the electronic device 10 pushes the hinge 23, the sliding member 21 partially slides out of the inputting member 20. The electronic device 10 is rotated away from the inputting member 20, which causes the hinge 23 and the supporting arm 24 to rotate away from the inputting member 20.

When the electronic device 10 is rotated to a required angle, a bottom of the electronic device 10 is supported on a top surface of the sliding member 21 and abuts a side surface of the inputting member 20. The first portion of the hinge 23 is rotated to be substantially parallel to the sliding member 21. The second portion of the supporting arm 24 supports the side surface of the electronic device 10, and the electronic device 10 is angled relative to the inputting member 20.

As the electronic device 10 is rotated further away from the inputting member 20, the sliding member 21 slides further out of the sliding slot 22. When the electronic device 10 is rotated to the required angle, the second portion of the supporting arm 24 supports the side surface of the electronic device 10.

As the electronic device 10 is rotated toward the inputting member 20, the sliding member 21 slides further in the sliding slot 22. When the electronic device 10 is rotated to the required angle, the second portion of the supporting arm 24 supports the side surface of the electronic device 10.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. An angle adjusting apparatus for adjusting an angle of an electronic device, comprising:
an inputting member defining a sliding slot at a bottom of the inputting member;
a sliding member slidably received in the sliding slot;
a hinge rotatably connected to the sliding member; and
a supporting arm rotatably connected to the hinge; wherein when the supporting arm moves the sliding member relative to the inputting member via the hinge, the sliding member partially slides in the sliding slot; the supporting arm is rotated round the hinge, the electronic device is placed on a connecting position between the inputting member and the sliding member; the supporting arm supporting the electronic device thereon; and
the electronic device has an angle relative to the inputting member.

2. The angle adjusting apparatus of claim 1, wherein when the electronic device is rotated to a required angle, the hinge is rotated to substantially parallel to the inputting member round the sliding member.

3. The angle adjusting apparatus of claim 2, wherein the electronic device and the supporting arm are substantially parallel to the inputting member and the sliding member, and the hinge is substantially perpendicular to the sliding member and the supporting arm when the electronic device and the inputting member are at an original state.

4. The angle adjusting apparatus of claim 3, wherein a first portion of the sliding member is received in the sliding slot; and a second portion of the sliding member is rotatably connected to a first portion of the hinge.

5. The angle adjusting apparatus of claim 4, wherein a second portion of the hinge is rotatably connected to a first portion of the supporting arm; and a second portion of the supporting arm movably supports a side surface of the electronic device thereon.

6. The angle adjusting apparatus of claim 5, wherein when the supporting arm is rotated to a required angle round the hinge, the first portion of the hinge is rotated to substantially parallel to the inputting member and the sliding member round the second portion of the sliding member; and the second portion of the supporting arm supports the side surface of the electronic device thereon.

7. The angle adjusting apparatus of claim 6, wherein as the electronic device is rotated further away from the inputting member, the sliding member slides further out of the sliding slot; and when the electronic device is rotated to the required angle, the second portion of the supporting arm supports the side surface of the electronic device thereon.

8. The angle adjusting apparatus of claim 7, wherein as the electronic device is rotated toward the inputting member, the sliding member slides further in the sliding slot; and
when the electronic device is rotated to the required angle, the second portion of the supporting arm supports the side surface of the electronic device thereon.

9. An angle adjusting apparatus for adjusting an angle of an electronic device, comprising:
an inputting member defining a sliding slot at a bottom of the inputting member;
a sliding member slidably received in the sliding slot;
a hinge rotatably connected to the sliding member; and
a supporting arm rotatably connected to the hinge; wherein when the supporting arm moves the sliding member relative to the inputting member via the hinge, the sliding member partially slides in the sliding slot; the supporting arm is rotated round the hinge and supports the electronic device thereon; and the electronic device is supported at different angles by the supporting arm according to different positions the sliding member sliding out of the inputting member.

10. The angle adjusting apparatus of claim 9, wherein when the electronic device is rotated to a required angle, the hinge is rotated to substantially parallel to the inputting member round the sliding member.

11. The angle adjusting apparatus of claim 10, wherein the electronic device and the supporting arm are substantially parallel to the inputting member and the sliding member, and the hinge is substantially perpendicular to the sliding member and the supporting arm when the electronic device and the inputting member are at an original state.

12. The angle adjusting apparatus of claim 11, wherein a first portion of the sliding member is received in the sliding slot; and a second portion of the sliding member is rotatably connected to a first portion of the hinge.

13. The angle adjusting apparatus of claim 12, wherein a second portion of the hinge is rotatably connected to a first portion of the supporting arm; and a second portion of the supporting arm movably supports on a side surface of the electronic device.

14. The angle adjusting apparatus of claim 13, wherein when the supporting arm is rotated to a required angle round the hinge, the first portion of the hinge is rotated to substantially parallel to the inputting member and the sliding member round the second portion of the sliding member; and the second portion of the supporting arm supports on the side surface of the electronic device.

15. The angle adjusting apparatus of claim 14, wherein as the electronic device is rotated further away from the inputting member, the sliding member slides further out of the sliding slot; and when the electronic device is rotated to the required angle, the second portion of the supporting arm supports the side surface of the electronic device thereon.

16. The angle adjusting apparatus of claim 15, wherein as the electronic device is rotated toward the inputting member, the sliding member slides further in the sliding slot;
and when the electronic device is rotated to the required angle, the second portion of the supporting arm supports the side surface of the electronic device thereon.
